(19) United States
(12) Patent Application Publication
(10) Pub. No.: US 2026/0343721 A1
(43) Pub. Date: Oct. 29, 2026

(54) THERMAL MONITORING FOR ELECTRONIC DEVICES

(71) Applicant: Aivres Systems Inc., Fremont, CA (US)

(72) Inventor: CHUN-HUNG LIN, New Taipei City (TW)

(21) Appl. No.: 19/718,772

(22) Filed: Jun. 24, 2026

(51) Int. Cl. H05K 1/02; H05K 1/181

(52) U.S. Cl. CPC H05K 1/0207; H05K 1/181; H05K 2201/10151

(57) ABSTRACT

A circuit board assembly includes a printed circuit board (PCB) and a temperature sensor disposed on the PCB. One or more thermal conducting traces are routed from a target location of the PCB to the temperature sensor and are configured to conduct heat from the target location to the temperature sensor. A thermal isolation region comprising a cut-out region is formed in a conductive layer of the PCB. The thermal isolation region surrounds at least a portion of the temperature sensor.

### TECHNICAL FIELD

The present disclosure generally relates to electronic devices and systems and, more specifically, to thermal monitoring for electronic devices.

### BACKGROUND

Modern electronic systems, such as high-performance computing platforms, increasingly operate at high power densities. Internal components such as high-current power connectors and busbar assemblies can be subjected to excessive heating. For example, conditions such as contact resistance degradation, mechanical vibrations, stress loosening, improper connections (e.g., improper fastener torque or misalignment), and plating wear from repeated plug insertions can generate excessive localized heat at these physical connection points. If unmanaged, the localized heat can lead to component deformation, short circuits, or severe damage to the system.

### SUMMARY

The present disclosure describes devices, circuits, systems, methods, and techniques for monitoring temperatures in circuit board assemblies and electronic systems.

In one aspect, this disclosure provides a circuit board assembly comprising: a printed circuit board (PCB); a temperature sensor disposed on the PCB; one or more thermal conducting traces routed from a target location of the PCB to the temperature sensor, the one or more thermal conducting traces being configured to conduct heat from the target location to the temperature sensor; and a thermal isolation region comprising a cut-out region formed in a conductive layer of the PCB, the thermal isolation region surrounding at least a portion of a heat transmission path between the target location and the temperature sensor.

In some implementations of the circuit board assembly, the one or more thermal conducting traces are configured to conduct heat from the target location to the temperature sensor without carrying a current from the target location to the temperature sensor.

In some implementations of the circuit board assembly, the temperature sensor is spaced apart from the target location by a minimal predefined distance.

In some implementations of the circuit board assembly, the thermal isolation region further surrounds at least a portion of the temperature sensor.

In some implementations of the circuit board assembly, the thermal isolation region is formed in multiple conductive layers of the PCB.

In some implementations of the circuit board assembly, a connector pin pad is disposed at the target location of the PCB.

In some cases, the connector pin pad is configured to receive a power connector configured to supply electrical power to the PCB.

In some implementations of the circuit board assembly, a conductive pad configured to receive a conductive busbar is disposed at the target location of the PCB.

In some cases, the conductive busbar is secured to the conductive pad by a fastener.

In some implementations of the circuit board assembly, at least a portion of the one or more thermal conducting traces is routed on an inner layer of the PCB using one or more vias, and wherein the temperature sensor is disposed on a surface layer of the PCB.

In some implementations of the circuit board assembly, the one or more thermal conducting traces comprise a pair of thermal conducting traces respectively connected to two terminals of the temperature sensor.

In some cases, the pair of thermal conducting traces are arranged in a substantially parallel routing along at least a portion of a length of the pair of thermal conducting traces.

In some implementations, the circuit board assembly further comprises a pair of conductive lines electrically coupled to respective terminals of the temperature sensor in an electrical differential configuration.

In some implementations of the circuit board assembly, the temperature sensor is a first temperature sensor, and the circuit board assembly further comprises a second temperature sensor configured to measure a reference temperature.

In some cases, the first temperature sensor and the second temperature sensor are configured to provide differential temperature measurements that compensate for environmental thermal effects.

In some implementations of the circuit board assembly, the temperature sensor comprises a thermistor, a thermal diode, or a digital temperature sensor integrated circuit.

In some cases, the temperature sensor comprises a negative temperature coefficient (NTC) thermistor.

In some implementations, the circuit board assembly further comprises a measurement circuit coupled to the temperature sensor and configured to generate a signal representative of temperature.

In some cases, the measurement circuit comprises an analog-to-digital converter (ADC).

In some implementations of the circuit board assembly, the temperature sensor comprises a ground terminal coupled to a ground plane of the PCB through a thermal relief connection.

In some implementations of the circuit board assembly, the conductive layer comprises a power plane of the PCB configured to provide electrical power to one or more components disposed on the PCB.

In some implementations, the circuit board assembly further comprises a controller configured to receive a sensor signal from the temperature sensor or a measurement circuit coupled to the temperature sensor, the controller being configured to compute a temperature based on the sensor signal.

In some cases, the controller is further configured to perform one or more thermal management actions based on the temperature.

In some cases, the thermal management actions comprise one or more of: generating an alarm, adjusting cooling, or disabling power to the PCB.

In another aspect, this disclosure provides a system comprising: a printed circuit board (PCB); a temperature sensor disposed on the PCB; one or more thermal conducting traces routed from a target location of the PCB to the temperature sensor, the one or more thermal conducting traces being configured to conduct heat from the target location to the temperature sensor; a thermal isolation region comprising a cut-out region formed in a conductive layer of the PCB, the thermal isolation region surrounding at least a portion of the temperature sensor; and a controller configured to receive a sensor signal from the temperature sensor or a measurement circuit coupled to the temperature sensor, the controller being configured to determine a temperature based on the sensor signal.

In some implementations of the system, the controller is further configured to perform one or more thermal management actions based on the temperature.

In some cases, the thermal management actions comprise one or more of: generating an alarm, adjusting cooling, or disabling power to the PCB.

In some implementations, the system comprises a computer server.

In some cases, the controller is implemented by a baseboard management controller (BMC) of the system.

In another aspect, this disclosure provides a method performed by an electronic system, the method comprising: sensing, by a thermal sensor disposed on a printed circuit board (PCB), heat conducted from a target location of the PCB via one or more thermal conducting traces routed from the target location to the thermal sensor, wherein at least a portion of the thermal sensor is surrounded by a thermal isolation region comprising a cut-out region formed in a conductive layer of the PCB; receiving, by a controller, a sensor signal from the temperature sensor or a measurement circuit coupled to the temperature sensor; and determining, by the controller, a temperature based on the sensor signal.

In some implementations, the method further comprises: performing, by the controller, one or more thermal management actions based on the temperature

The details of one or more implementations of the subject matter of this specification are set forth in the Detailed Description, the Claims, and the accompanying drawings. Other features, aspects, and advantages of the subject matter will become apparent to those of ordinary skill in the art from the Detailed Description, the Claims, and the accompanying drawings.

### BRIEF DESCRIPTION OF DRAWINGS

FIG. 1 illustrates an example circuit board assembly that includes a thermal sensor configured to sense the temperature of a target location on the circuit board.

FIG. 2 illustrates a layered view of an example circuit board assembly.

FIG. 3 illustrates an example electronic system that includes components for monitoring the temperature of a target location of a circuit board.

FIG. 4 is a flowchart illustrating an example process for monitoring the temperature of a target location of a circuit board.

FIG. 5 illustrates an example computing device.

FIG. 6 illustrates an example computing system.

Like reference numbers and designations in the various drawings indicate like elements.

### DETAILED DESCRIPTION

An electronic system, such as an artificial intelligence (AI) server or a high-performance computing (HPC) platform, often operates at a high power density, where the system may consume substantial electrical current within a compact physical footprint. Consequently, internal components, such as high-current power connectors, busbar attachment points, and high-power converter integrated circuits (ICs), can face thermal risks caused by conditions such as contact resistance degradation, mechanical vibrations, stress loosening, improper fastener torque, misalignment, or plating wear from repeated plug insertions. If left unchecked, this localized heating can exceed the thermal tolerance of the surrounding materials. For instance, excessive heat can cause a connector's plastic housing to soften and deform, potentially leading to positive and negative terminal short circuits, severe hardware damage, system downtime, or even catastrophic data center fires.

Existing thermal monitoring solutions frequently struggle to balance cost, structural reliability, and measurement accuracy. For example, customized “smart cables” that embed sensors directly within the cable assembly can be expensive and can be structurally fragile, as the solder joints connecting the sensors are prone to fracturing under the bending stresses of the cables. Another common approach is mounting temperature sensors on the exterior of a connector's plastic housing; however, this can result in significant measurement time lag. Because plastic is a poor thermal conductor, a rapid temperature increase at the internal electrical contacts is not immediately detected on the exterior. Furthermore, external sensor readings are often skewed by ambient cooling airflow within the system, causing the recorded temperatures to be substantially lower than the actual internal contact temperatures.

Implementations of the present disclosure provide devices, systems, methods, and techniques that can provide accurate, cost-effective, and real-time temperature monitoring for circuit board assemblies and electronic devices. In some implementations, a temperature sensor is disposed on a printed circuit board (PCB) spaced apart from a target location (e.g., a power connector pin pad or a conductive busbar pad) by a predefined distance, and is connected to the target location via one or more thermal conducting traces.

The PCB can include large conductive planes, e.g., ground planes or power planes. These are a particular type of conductive layer, often formed as continuous sheets of copper. While power pins can be connected to these conductive planes to reduce electrical resistance, these planes can act as heat sinks and disperse the heat. To prevent the PCB's conductive planes from acting as heat sinks and dispersing the heat, a thermal isolation region (e.g., a keep-out or cut-out region) can be formed in a conductive layer of the PCB surrounding at least a portion of a heat transmission path (e.g., the thermal conducting traces) and/or the temperature sensor. By removing the conductive material surrounding the sensor, this architecture creates a “thermal focusing” effect that channels the heat predominantly along the designated conductive traces directly to the thermal sensor, thereby enabling the sensor to measure the temperature of the target location with high accuracy and minimal lateral heat loss.

The subject matter described in the present disclosure can be implemented in particular implementations so as to realize one or more of the following technical advantages, effects, and/or benefits.

For example, the described techniques can achieve sensitive and accurate thermal monitoring with high cost-efficiency. By utilizing surface-mounted temperature sensors (such as thermistors) and integrating the thermal routing directly into the PCB layout, the described techniques can avoid the need for expensive customized smart cables. This allows system manufacturers to utilize standard, multi-sourced connectors and cables, thereby minimizing supply chain risks. Furthermore, because the thermal conducting traces can be implemented within or on the PCB itself, the sensing architecture can be highly reliable and structurally robust against the physical damage or wire breakage that affects externally wired sensors.

The described techniques also significantly improve measurement sensitivity and accuracy. The thermal isolation region can effectively reduce heat dissipation into the conductive layers, e.g., the main power planes, of the PCB. This creates a “thermal focusing” effect that guides heat to travel predominantly from the high-temperature connection point to the sensor. This architecture can overcome the thermal lag of existing housing-mounted sensors by leveraging the high thermal conductivity of the conductive traces to provide an accurate, real-time representation of the internal contact temperature.

In some implementations, the system can utilize a balanced thermal-conduction routing architecture, where a pair of thermal conducting traces are routed symmetrically and closely parallel to one another. This balanced routing arrangement can cause the pair of thermal conducting traces to have similar thermal characteristics and to experience similar environmental conditions in high-density server environments. As a result, the balanced routing arrangement can reduce measurement errors caused by asymmetric thermal interference, such as localized airflow cooling or localized ambient heating affecting one trace more than the other, thereby reducing the likelihood of false thermal alarms.

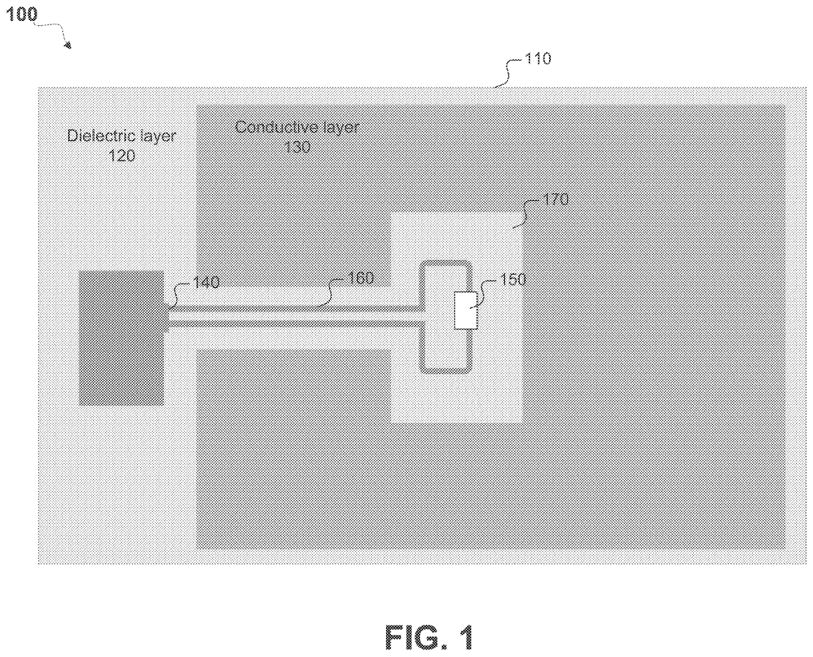

FIG. 1 illustrates an example circuit board assembly 100 configured for thermal monitoring. The circuit board assembly 100 can be implemented within an electronic system, such as a high-performance computing platform, an artificial intelligence (AI) server, or another electronic device subject to high thermal loads. The circuit board assembly 100 includes a printed circuit board (PCB) 110 having at least one dielectric layer 120 and at least one conductive layer 130.

The circuit board assembly 100 includes a target location 140 on the PCB 110. The target location 140 can represent a position or area on the PCB 110 where a connection point or component location that generates significant heat during operation is located, such as a high-current power connection point. For example, a connector pin pad configured to receive a power connector that supplies electrical power to the PCB 110 can be disposed at the target location 140. In another example, a conductive pad configured to receive a conductive busbar, which may be secured to the conductive pad by a fastener (e.g., a screw), can be disposed at the target location 140. Busbars are heavily utilized in high-density systems, such as AI servers, because these systems consume extremely high electrical currents where traditional cable-based power distribution becomes inefficient, bulky, and difficult to cool. However, improper fastener torque or mechanical loosening over time can cause these busbar connections to generate severe localized heat, making the disclosed thermal monitoring techniques highly valuable in these AI server environments. Additional examples of physical items located at the target location 140 can include high-power electronic components, such as a power converter IC or a MOSFET that generates significant heat during operation.

A temperature sensor 150 is disposed on the PCB 110 and is spaced apart from the target location 140 by a minimal predefined distance. In some implementations, the temperature sensor 150 can be mounted on a surface of the PCB 110 at a location that is apart from the target location 140. In some cases, the temperature sensor 150 can be a surface-mounted device (SMD) that is physically attached to an outer surface of the PCB 110. The temperature sensor 150 can be implemented as, for example, a negative temperature coefficient (NTC) thermistor, a thermal diode, or a digital temperature sensor integrated circuit.

In some implementations, the temperature sensor 150 is spaced apart from the target location 140 with a distance selected to reduce mechanical stress and/or improve measurement accuracy. For example, spacing the sensor apart from a power connector pin pad helps prevent the sensor from being damaged by the bending stresses and physical force applied to the PCB when a heavy cable connector is repeatedly plugged and unplugged. The distance can be selected according to the mechanical clearance requirements of the connector and the expected bending radius of the PCB during plug insertion. For example, the minimal distance can be a distance sufficient to place the temperature sensor 150 outside of a mechanical strain zone of the target location 140, such as several millimeters, several centimeters, or more, depending on the physical footprint and thermal profile of the target location 140.

To accurately measure the temperature of the target location 140 without placing the temperature sensor 150 directly at the physical connection point (which may be subject to mechanical stress or spatial constraints), the circuit board assembly 100 can utilize one or more thermal conducting traces 160. The thermal conducting trace 160 is routed from the target location 140 to the temperature sensor 150, and is configured to conduct heat from the target location 140 to the temperature sensor 150. In some implementations, the thermal conducting trace 160 is utilized primarily for heat conduction, and is configured to conduct heat without carrying an active load current from the target location 140 to the temperature sensor 150.

In some cases, the one or more thermal conducting traces 160 can be implemented as copper traces integrated directly into the layout of the printed circuit board (PCB) 110. By forming the thermal conducting traces 160 as etched copper traces directly on the PCB rather than utilizing separate soldered wires or fragile external “smart cables,” the system can maintain structural reliability and avoid wire breakage issues.

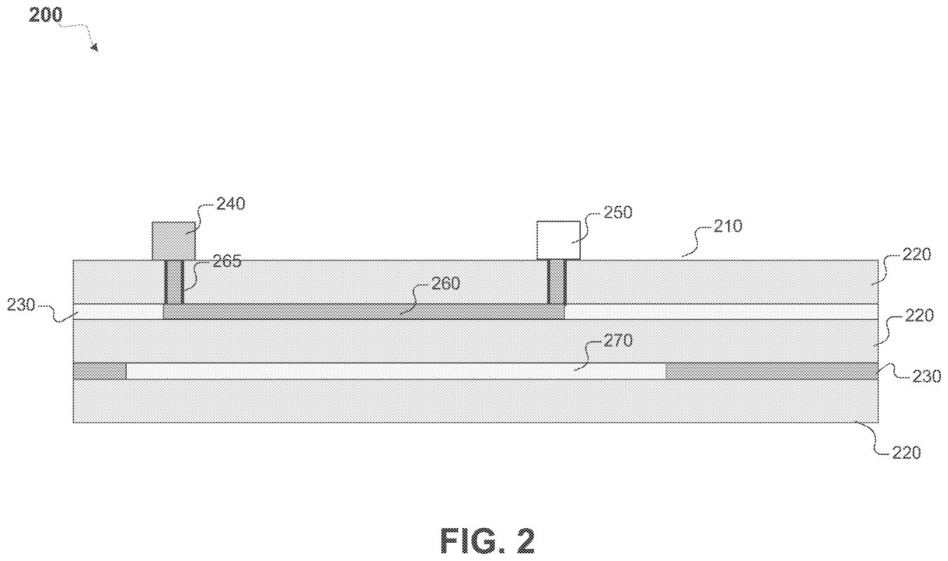

To improve measurement sensitivity and prevent conducted heat from dissipating into surrounding layers of the PCB 110, the circuit board assembly 100 includes a thermal isolation region 170. The thermal isolation region 170 can include a cut-out region (or void) formed in the conductive layer 130 of the PCB 110, which surrounds at least a portion of a heat transmission path between the target location 140 and the temperature sensor 150 (e.g., surrounding at least a portion of the thermal conducting trace 160). In some implementations, the thermal isolation region 170 can surround both the temperature sensor 150 and the thermal conducting trace 160. In some cases, as shown in FIG. 1, the thermal conducting trace 160 can be on the same layer as the conductive layer 130 that forms the thermal isolation region 170. That is, the thermal conducting trace 160 can be fabricated as an etched copper trace directly within the same conductive layer 130 from which the cut-out region is selectively etched. In some cases, as will be described with reference to FIG. 2, at least a portion of the thermal conducting trace can be routed on a different layer (e.g., an inner layer of the PCB) from the thermal isolation region to conserve surface layout space, utilizing one or more vias to bridge the inner-layer routing to the surface-mounted temperature sensor.

Typically, high-current pins can be connected to large conductive layers (e.g., power planes or ground planes) to lower electrical resistance. However, because large conductive layers (e.g., power planes or ground planes) can act as large heat sinks, removing the conductive material in the thermal isolation region 170 can create a thermal focusing effect. This effect channels and guides heat to travel predominantly along the narrow path of the thermal conducting trace 160 directly to the temperature sensor 150, thereby minimizing lateral heat dissipation and providing a highly accurate representation of the temperature at the target location 140.

In some cases, the thermal isolation region 170 can be formed during the manufacturing process of the printed circuit board (PCB) 110. For instance, the PCB 110 is typically manufactured using dielectric substrate materials, such as fiberglass, coated with layers of copper foil. The thermal isolation region 170 can be formed by selectively etching away the unwanted copper foil from the area surrounding the temperature sensor 150 and the thermal conducting traces 160. This subtractive manufacturing step leaves the underlying dielectric substrate exposed without requiring specialized mechanical drilling or adding substantial fabrication costs. In some implementations, the resulting cut-out region is absent of conductive materials. Additionally or alternatively, in some embodiments, the cut-out region can include or be filled with a thermally insulating material to further restrict lateral heat dissipation.

To further prevent conducted heat from dissipating away from the temperature sensor, in some cases, the temperature sensor can include a ground terminal (e.g., a GND pad) that is coupled to a ground plane of the PCB, e.g., through a thermal relief connection, rather than a solid or full-coverage copper connection. A thermal relief connection can include a conductive pad connected to the surrounding bulk copper plane by one or more narrow conductive traces (sometimes referred to as spokes or webs), which are separated by voided regions. While these narrow spokes provide a sufficient electrical pathway to ground the component, their restricted cross-sectional area can create a high thermal resistance. Using a thermal relief connection pattern restricts the rate of thermal transfer and reduces the heat that escapes from the sensor into the PCB's massive ground plane. By minimizing this heat loss, the temperature sensor can more accurately retain the conducted heat and reflect the true temperature of the target location.

To further enhance thermal measurement consistency and accuracy, the one or more thermal conducting traces 160 can include a pair of thermal conducting traces respectively connected to two terminals of the temperature sensor 150. The pair of thermal conducting traces can be arranged in a symmetrical and substantially parallel routing along at least a portion of a length of the pair of thermal conducting traces from the target location 140 to the temperature sensor 150. This arrangement can provide a balanced thermal-conduction configuration in which the pair of thermal conducting traces have similar thermal characteristics and are exposed to similar environmental conditions along their routing paths. Because both traces may experience similar ambient airflow, ambient heating, or nearby thermal influences, the configuration can reduce measurement error caused by asymmetric thermal interference, such as localized cooling or localized heating that would otherwise affect one trace more than the other. In this way, the balanced routing can reduce thermal mismatch between the conductive paths and improve the accuracy and consistency of the temperature measurement obtained from the temperature sensor 150.

In some implementations, the connection of the temperature sensor 150 to downstream circuits can include a pair of conductive lines electrically coupled to respective terminals of the temperature sensor 150 in an electrical differential configuration. In this electrical architecture, the pair of connection traces connects the sensor terminals to a downstream measurement circuit configured to read a differential voltage. By utilizing an electrical differential architecture, the system can measure a voltage differential to effectively cancel out common-mode electrical noise that is common in high-density electronic systems. Because the traces are routed closely together and in parallel, electromagnetic interference (EMI) from surrounding high-current components induces equal noise voltages on both traces. The differential measurement circuit subsequently subtracts and eliminates this common-mode noise, significantly improving the signal-to-noise ratio and preventing false thermal alarms.

In some implementations, to further improve measurement accuracy, the circuit board assembly 100 can employ a dual-sensor reference architecture for differential thermal monitoring. In such configurations, the temperature sensor 150 is a first temperature sensor (e.g., a “signal” sensor) that is connected directly to the target location 140 via the thermal conducting traces 160. The circuit board assembly 100 further includes an adjacent second temperature sensor (not shown) configured to measure a reference temperature. The temperature sensor 150 and the second temperature sensor are configured to work together to provide differential temperature measurements. By comparing the readings from both sensors, the system can effectively filter out and compensate for environmental background thermal noise and other environmental thermal effects present in the system, causing the calculated temperature to accurately reflect the heat originating from the target location 140.

The circuit board assembly 200 includes a printed circuit board (PCB) 210 including at least one PCB dielectric layer 220 and at least one PCB conductive layer 230. In many applications, the PCB 210 is a multi-layer board including a plurality of dielectric and conductive layers configured to route signals and provide power to various components. In the particular example shown in FIG. 2, the printed circuit board (PCB) 210 includes an alternating arrangement of three dielectric layers 220 and two conductive layers 230. However, it should be understood that more or fewer layers can be utilized based on specific design needs or system requirements.

The circuit board assembly 200 includes a target location 240 and a temperature sensor 250 disposed on the PCB 210. As illustrated, the temperature sensor 250 is disposed on a surface layer of the PCB 210 to facilitate the mounting of a physical component, such as a surface-mounted device (SMD) thermistor. A thermal isolation region 270 is formed in the PCB conductive layer 230. In some implementations, the thermal isolation region 270 can be formed across multiple conductive layers of the PCB 210 to prevent heat from dispersing into surrounding main power or ground planes. For example, the thermal isolation region 270 can be formed by selectively removing copper in a top power plane layer where the temperature sensor 250 is mounted, as well as in adjacent inner ground plane layers or other main power planes.

To route heat from the target location 240 to the temperature sensor 250, the circuit board assembly 200 includes at least one thermal conducting trace 260. To conserve surface layout space and accommodate dense component placements on the surface of the PCB 210, in some cases, at least a portion of the thermal conducting trace 260 can be routed on an inner layer (e.g., an internal conductive layer sandwiched between two dielectric layers) of the PCB 210. To bridge the inner-layer routing to the surface-mounted components, the circuit board assembly 200 utilizes one or more vias 265. The via 265 can extend through one or more layers of the PCB 210 to thermally and electrically couple the thermal conducting trace 260 located on the inner layer to the temperature sensor 250 located on the surface layer. This inner-layer routing architecture provides flexibility in the PCB design without sacrificing the thermal focusing benefits provided by the thermal isolation region 270.

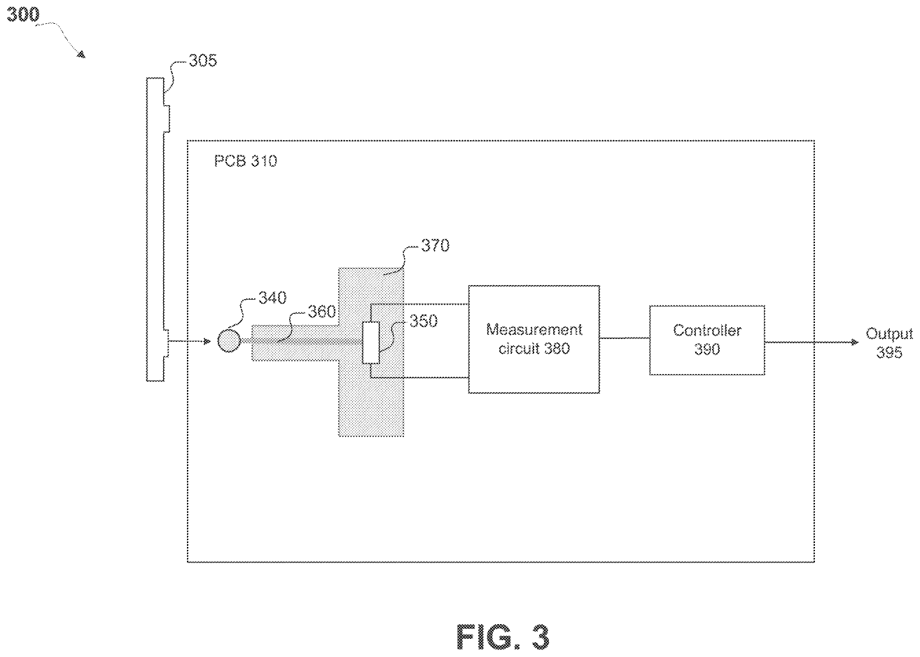

FIG. 3 illustrates a block diagram of an example system 300 for thermal monitoring. The system 300 includes a circuit board assembly, which can be the same as or similar to the circuit board assemblies 100 or 200 described with reference to FIG. 1 and FIG. 2. The circuit board assembly includes a printed circuit board (PCB) 310 having a target location 340 which can be a location for coupling to a busbar 305, a temperature sensor 350, at least one thermal conducting trace 360, and a thermal isolation region 370.

To process the thermal readings, the system 300 can further include a measurement circuit 380 and, in some cases, a controller 390. The measurement circuit 380 is electrically coupled to the temperature sensor 350 and is configured to generate a sensor signal representative of a temperature. In some implementations, such as when the temperature sensor 350 is an analog device like a negative temperature coefficient (NTC) thermistor or a thermal diode, the measurement circuit 380 includes an analog-to-digital converter (ADC). The ADC converts an analog voltage reading from the temperature sensor 350 into a digital sensor signal. In some cases, if the temperature sensor 350 is implemented as a digital temperature sensor integrated circuit, the functionality of the measurement circuit 380 may be integrated directly within the sensor component itself.

In a particular example, when the temperature sensor 350 is a negative temperature coefficient (NTC) thermistor, the electrical resistance of the thermistor can change in response to the conducted temperature. As the temperature increases, the resistance of the NTC thermistor decreases. To measure this change, the measurement circuit 380 can be configured as a voltage divider circuit, where the NTC thermistor is connected in series with an additional reference resistor and supplied with a reference voltage, such as 3.3 volts. As the thermistor's resistance changes with temperature, the analog voltage across the thermistor correspondingly changes. The analog-to-digital converter (ADC) can then convert the analog voltage and convert it into a digital sensor signal for downstream processing.

The measurement circuit 380 can be communicatively coupled to the controller 390. The controller 390 is configured to receive the sensor signal from the measurement circuit 380 (or directly from the temperature sensor 350) and determine a real-time temperature based on the sensor signal. For example, in an implementation utilizing an NTC thermistor, the controller 390 can calculate the actual real-time temperature by converting the digital voltage reading received from the measurement circuit 380. The controller 390 can determine that a specific voltage reading, such as 1.5 volts, corresponds to a specific temperature value, effectively mapping the sensor signal to a temperature reading of the target location 340. To implement this mapping, the controller 390 can utilize a set of reference values stored in a memory component of the system (e.g., a local non-volatile memory or firmware storage). These reference values can be determined during a system calibration phase, dynamically calculated, or derived directly from manufacturer specifications for the temperature sensor 350. The reference values can be stored in various formats, such as a look-up table (LUT), a digital calibration curve, or as specific mathematical coefficients for a temperature conversion algorithm (e.g., the Steinhart-Hart equation). During operation, upon receiving the digital voltage reading from the measurement circuit 380, the controller 390 queries the memory to retrieve the corresponding reference data. The controller 390 then applies this data, e.g., by directly matching the voltage reading to a discrete temperature in the look-up table, interpolating between adjacent stored data points, or executing the conversion algorithm, to compute the real-time temperature of the target location 340.

The controller can be implemented with any suitable circuit design. In some implementations, the system 300 includes a computer server, and the controller 390 is implemented by a baseboard management controller (BMC) of the system. The BMC can read the sensor signal from the measurement circuit 380 via a communication interface, such as an I2C bus.

Based on the determined temperature, the controller 390 is further configured to perform one or more thermal management actions, represented in FIG. 3 as an output 395. For example, the controller 390 can execute predefined safety policies by comparing the determined temperature against expected operational thresholds. If the temperature indicates an abnormal heating condition, such as excessive localized heat caused by a loosely secured busbar or contact resistance degradation at a power connector, the controller 390 can utilize the output 395 to mitigate the thermal risk. These thermal management actions can include generating an alarm to alert maintenance personnel, dynamically adjusting system cooling (e.g., accelerating fan speeds), or disabling the power supply to the PCB 310 to prevent catastrophic thermal damage.

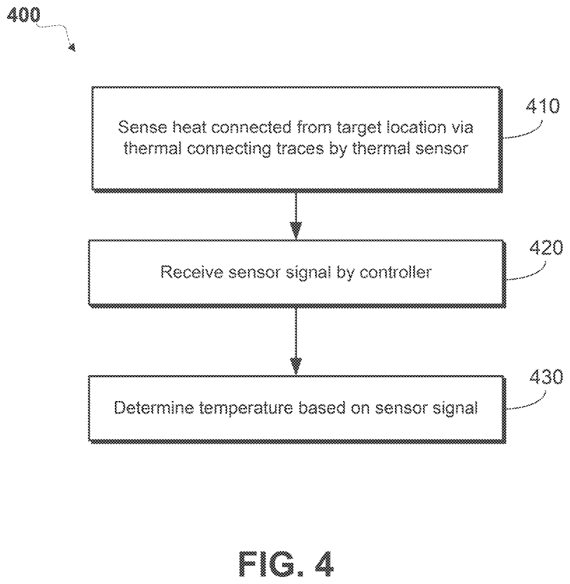

FIG. 4 is a flowchart illustrating an example process 400 for determining a temperature in an electronic system. The process 400 can be performed by an electronic system, such as the system 300 described with reference to FIG. 3, utilizing the circuit board assemblies 100 or 200 described with reference to FIG. 1 and FIG. 2.

At 410, a thermal sensor disposed on a printed circuit board (PCB) senses heat conducted from a target location of the PCB. The heat is conducted via one or more thermal conducting traces routed from the target location to the thermal sensor. As described previously, at least a portion of the thermal sensor is surrounded by a thermal isolation region including a cut-out region formed in a conductive layer of the PCB. This thermal isolation region focuses the heat toward the sensor and minimizes lateral heat dissipation into surrounding conductive layers.

At 420, a controller receives a sensor signal. Depending on the specific architecture and the type of temperature sensor utilized, the sensor signal can be received directly from the temperature sensor or from a measurement circuit (e.g., an analog-to-digital converter) coupled to the temperature sensor.

At 430, the controller determines a temperature based on the sensor signal. For example, a baseboard management controller (BMC) can calculate the real-time temperature of a target location, such as a high-current power connection point, based on a digitized voltage reading.

In some implementations, the process 400 can further include performing, by the controller, one or more thermal management actions based on the determined temperature. For instance, if the determined temperature exceeds a predefined safety threshold, the controller can execute safety policies to mitigate the thermal risk, which can include generating an alarm, adjusting system cooling components (e.g., accelerating fan speeds), or disabling electrical power supplied to the PCB.

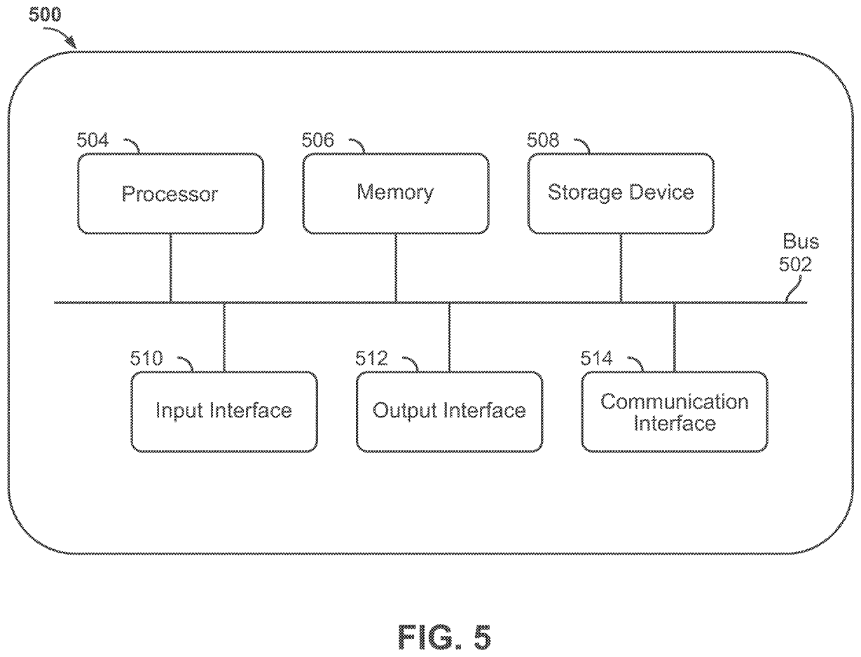

FIG. 5 illustrates an example architecture of a computing device 500, which can be an implementation of the system 300 or the controller 390 described with reference to FIG. 3. The computing device 500 includes a processor 504, memory 506, a storage component 508, an input interface 510, an output interface 512, and a communication interface 514, all communicatively coupled via a bus 502. The bus 502 can represent the electrical pathways on one or more circuit boards of the electronic device.

Processor 504 can represent integrated circuitry on one or more circuit boards, such as one or more central processing units (CPUs), a graphics processing unit (GPU), a Baseboard Management Controller (BMC), a Complex Programmable Logic Device (CPLD), and/or other processing circuitry. This integrated circuitry can generate and process signals used to perform one or more processes described herein, such as computing a temperature based on a sensor signal and performing thermal management actions. Memory 506 and storage component 508 can include various forms of computer-readable media for storing data and software instructions.

The input interface 510 and output interface 512 can collectively represent interface components described herein. For example, the input interface 510 can include components and/or interfaces used to receive information, such as sensor signals from a temperature sensor or a measurement circuit. The output interface 512 can include components used to provide output information, such as visual alarms via one or more light indicators (e.g., LEDs), a display device, and/or an audible output device. The communication interface 514 can include components such as a network management interface configured to transmit temperature data and thermal status information to a remote device.

In operation, the processor 504 can execute software instructions stored in memory 506 or storage component 508 to perform one or more processes described herein. In some implementations, hardwired circuitry, such as the CPLD, can be used in place of or in combination with software instructions. The number and arrangement of components illustrated in FIG. 5 are provided as an example, and other configurations are possible.

Bus 502 includes a component that permits communication among the components of the computing device 500. In some embodiments, processor 504 is implemented in hardware, software, or a combination of hardware and software. In some examples, processor 504 includes a processor (e.g., a central processing unit (CPU), a graphics processing unit (GPU), an accelerated processing unit (APU), and/or the like), a digital signal processor (DSP), and/or any processing component (e.g., a field-programmable gate array (FPGA), an application specific integrated circuit (ASIC), and/or the like) that can be programmed to perform at least one function. Memory 506 includes random access memory (RAM), read-only memory (ROM), and/or another type of dynamic and/or static storage device (e.g., flash memory, magnetic memory, optical memory, and/or the like) that stores data and/or instructions for use by processor 504.

Storage component 508 stores data and/or software related to the operation and use of the computing device 500. In some examples, storage component 508 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 510 includes a component that permits the computing device 500 to receive information, such as via user input (e.g., a touchscreen display, a keyboard, a keypad, a mouse, a button, a switch, a microphone, a camera, and/or the like). Additionally or alternatively, in some embodiments input interface 510 includes a sensor that senses information (e.g., a global positioning system (GPS) receiver, an accelerometer, a gyroscope, and/or the like). Output interface 512 includes a component that provides output information from the computing device 500 (e.g., a display, a speaker, one or more light-emitting diodes (LEDs), and/or the like).

In some embodiments, communication interface 514 includes a transceiver-like component (e.g., a transceiver, a separate receiver and transmitter, and/or the like) that permits the computing device 500 to communicate with other devices via a wired connection, a wireless connection, or a combination of wired and wireless connections. In some examples, communication interface 514 permits the computing device 500 to receive information from another device and/or provide information to another device. In some examples, communication interface 514 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, the computing device 500 performs one or more processes described herein. The computing device 500 performs these processes based on processor 504 executing software instructions stored by a computer-readable medium, such as memory 506 and/or storage component 508. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 506 and/or storage component 508 from another computer-readable medium or another device via communication interface 514. When executed, software instructions stored in memory 506 and/or storage component 508 cause processor 504 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 506 and/or storage component 508 includes data storage or at least one data structure (e.g., a database and/or the like). The computing device 500 is capable of receiving information from, storing information in, communicating information to, or searching information stored in the data storage or the at least one data structure in memory 506 or storage component 508. In some examples, the information includes network data, input data, output data, or any combination thereof.

In some embodiments, the computing device 500 is configured to execute software instructions that are either stored in memory 506 and/or in the memory of another device (e.g., another device that is the same as or similar to the computing device 500). As used herein, the term “module” refers to at least one instruction stored in memory 506 and/or in the memory of another device that, when executed by processor 504 and/or by a processor of another device (e.g., another device that is the same as or similar to the computing device 500) cause the computing device 500 (e.g., at least one component of the computing device 500) to perform one or more processes described herein. In some embodiments, a module is implemented in software, firmware, hardware, and/or the like.

The number and arrangement of components illustrated in FIG. 5 are provided as an example. In some embodiments, the computing device 500 can include additional components, fewer components, different components, or differently arranged components than those illustrated in FIG. 5. Additionally or alternatively, a set of components (e.g., one or more components) of the computing device 500 can perform one or more functions described as being performed by another component or another set of components of the computing device 500.

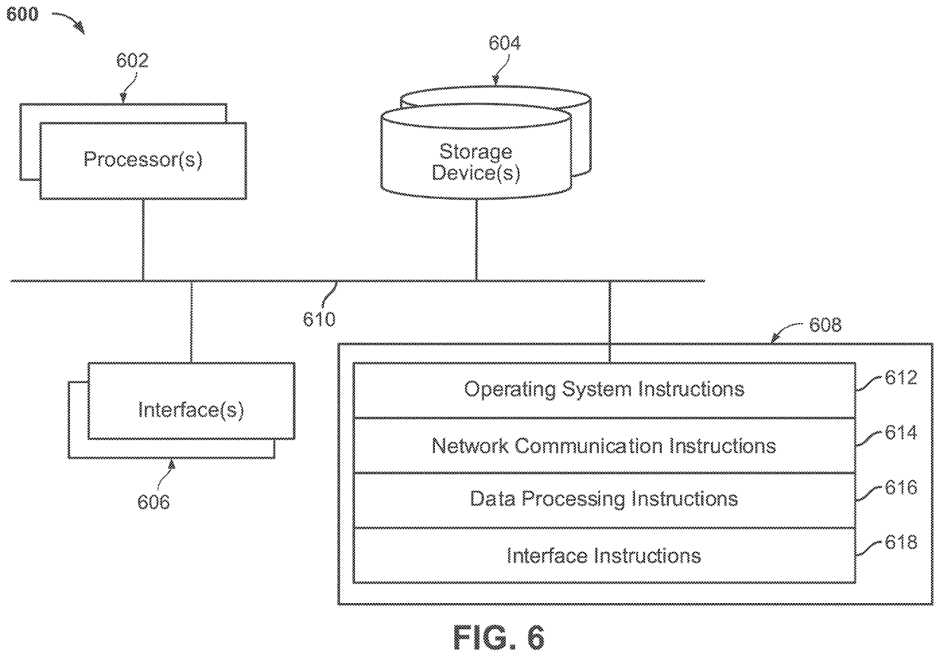

FIG. 6 illustrates an example architecture 600 of a computing system, such as a computer server, which can have a thermal monitoring function as described in FIG. 3 and FIG. 4. The computing system 600 provides a broader context for the previously described components. Other architectures are possible, including architectures with more or fewer components.

The architecture 600 can include one or more processors 602, one or more storage devices 604, one or more network interfaces 606, and one or more computer-readable media 608. These components can exchange communications and data over one or more communication channels 610 (e.g., one or more buses), such as the bus 502 described with reference to FIG. 5. The processor(s) 602 can include integrated circuitry described previously, such as a CPU and/or a management controller (e.g., a BMC) that can implement one or more processes described herein. The network interface(s) 606 can include a network management interface configured to transmit temperature readings, thermal alerts, and/or diagnostic information to a remote device, and the storage device(s) 604 can include one or more local storage devices.

The term “computer-readable medium” refers to a non-transitory medium that participates in providing instructions to the processor(s) 602 for execution, including non-volatile media (e.g., optical or magnetic disks) and volatile media (e.g., memory). The computer-readable medium(s) 608 can store various instructions, including an operating system 612, a network communications module 614, data processing instructions 616, and interface instructions 618.

Operating systems can perform basic tasks, for example, recognizing input from and providing output to devices, and managing traffic on the communication channels. The network communications module 614 can manage data transfer through interfaces such as the network management interface using communication protocols (e.g., TCP/IP, HTTP). Data processing instructions 616 include software for implementing one or more processing operations described herein. Furthermore, the interface instructions 618 can include firmware and/or software for a management controller to interface with the temperature sensors, measurement circuits (e.g., ADCs), and manage thermal management functions.

The architecture 600 can be implemented in various configurations, including as a single server or as part of a larger system, such as a cloud computing environment with multiple server computers in a local or distributed network each having one or more processing cores. Architecture 600 can be implemented in a parallel processing or peer-to-peer infrastructure or on a single device with one or more processors. Software can include multiple software components or can be a single body of code.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage media. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application-specific integrated circuit (ASIC). In some implementations, the computer or computer-implemented system or special-purpose logic circuitry (or a combination of the computer or computer-implemented system and special-purpose logic circuitry) can be hardware-or software-based (or a combination of both hardware-and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer-readable media for storing computer program instructions and data can include all forms of permanent/non-permanent or volatile/non-volatile memory, media and memory devices, including by way of example semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto-optical disks; and optical memory devices, for example, digital versatile/video disc (DVD), compact disc (CD)-ROM, DVD+/−R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user's mobile computing device in response to requests received from the web browser).

The term “graphical user interface” (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances.

As used herein, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or, A and B.” As used herein, the term “and/or” as used herein refers to and encompasses any and all possible combinations of one or more of the associated listed terms. For example, the term “A and/or B” means that either option A, option B, or both options A and B are possible, where A and B may be singular or plural.

As used herein, the term “based on” can be directly based on or indirectly based on. For example, the phrase “based on a voltage” can be interpreted to cover: i) directly based on the voltage; i) indirectly based on the voltage, e.g., directly based on a signal (or voltage) that is generated based on (either directly or indirectly) the voltage. As used herein, the term “about” or “approximately” can allow for a degree of variability in a value or range, for example, within 10%, within 5%, or within 1% of a stated value or of a stated limit of a range. As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

In addition, the phraseology or terminology employed in the present disclosure, and not otherwise defined, is for the purpose of description only and not of limitation. Any use of section headings is intended to aid reading of the document and is not to be interpreted as limiting; information that is relevant to a section heading may occur within or outside of that particular section.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

The breadth and scope of the present disclosure should not be limited by any of the above-described exemplary implementations, but should be defined only in accordance with the following claims and their equivalents.

1. A circuit board assembly comprising:
a printed circuit board (PCB);
a temperature sensor disposed on the PCB;
one or more thermal conducting traces routed from a target location of the PCB to the temperature sensor, the one or more thermal conducting traces being configured to conduct heat from the target location to the temperature sensor; and
a thermal isolation region comprising a cut-out region formed in a conductive layer of the PCB, the thermal isolation region surrounding at least a portion of a heat transmission path between the target location and the temperature sensor.

2. The circuit board assembly according to claim 1, wherein a connector pin pad is disposed at the target location of the PCB.

3. The circuit board assembly according to claim 2, wherein the connector pin pad is configured to receive a power connector configured to supply electrical power to the PCB.

4. The circuit board assembly according to claim 1, wherein a conductive pad configured to receive a conductive busbar is disposed at the target location of the PCB.

5. The circuit board assembly according to claim 4, wherein the conductive busbar is secured to the conductive pad by a fastener.

6. The circuit board assembly according to claim 1, wherein at least a portion of the one or more thermal conducting traces is routed on an inner layer of the PCB using one or more vias, and wherein the temperature sensor is disposed on a surface layer of the PCB.

7. The circuit board assembly according to claim 1, wherein the one or more thermal conducting traces comprise a pair of thermal conducting traces respectively connected to two terminals of the temperature sensor.

8. The circuit board assembly according to claim 1, wherein the temperature sensor comprises a thermistor, a thermal diode, or a digital temperature sensor integrated circuit.

9. The circuit board assembly according to claim 1, further comprising a measurement circuit coupled to the temperature sensor and configured to generate a signal representative of temperature.

10. The circuit board assembly according to claim 9, wherein the measurement circuit comprises an analog-to-digital converter (ADC).

11. The circuit board assembly according to claim 1, wherein the temperature sensor comprises a ground terminal coupled to a ground plane of the PCB through a thermal relief connection.

12. The circuit board assembly according to claim 1, wherein the conductive layer comprises a power plane of the PCB configured to provide electrical power to one or more components disposed on the PCB.

13. The circuit board assembly according to claim 1, further comprising a controller configured to receive a sensor signal from the temperature sensor or a measurement circuit coupled to the temperature sensor, the controller being configured to compute a temperature based on the sensor signal.

14. The circuit board assembly according to claim 13, wherein the controller is further configured to perform one or more thermal management actions based on the temperature.

15. The circuit board assembly according to claim 14, wherein the thermal management actions comprise one or more of: generating an alarm, adjusting cooling, or disabling power to the PCB.

16. A system comprising:
a printed circuit board (PCB);
a temperature sensor disposed on the PCB;
one or more thermal conducting traces routed from a target location of the PCB to the temperature sensor, the one or more thermal conducting traces being configured to conduct heat from the target location to the temperature sensor;
a thermal isolation region comprising a cut-out region formed in a conductive layer of the PCB, the thermal isolation region surrounding at least a portion of the temperature sensor; and
a controller configured to receive a sensor signal from the temperature sensor or a measurement circuit coupled to the temperature sensor, the controller being configured to determine a temperature based on the sensor signal.

17. The system of claim 16, wherein the controller is further configured to perform one or more thermal management actions based on the temperature.

18. The system of claim 16, wherein the system comprises a computer server.

19. The system of claim 18, wherein the controller is implemented by a baseboard management controller (BMC) of the system.

20. A method performed by an electronic system, the method comprising:
sensing, by a thermal sensor disposed on a printed circuit board (PCB), heat conducted from a target location of the PCB via one or more thermal conducting traces routed from the target location to the thermal sensor, wherein at least a portion of the thermal sensor is surrounded by a thermal isolation region comprising a cut-out region formed in a conductive layer of the PCB;
receiving, by a controller, a sensor signal from the temperature sensor or a measurement circuit coupled to the temperature sensor; and
determining, by the controller, a temperature based on the sensor signal.
